(19) United States
(12) Patent Application Publication
(10) Pub. No.: US 2024/0153822 A1
(43) Pub. Date: May 9, 2024

(54) SEMICONDUCTOR CHIP MANUFACTURING METHOD AND SUBSTRATE PROCESSING APPARATUS

(71) Applicant: Tokyo Electron Limited, Tokyo (JP)

(72) Inventors: Yohei YAMASHITA, Kikuchi-gun, Kumamoto (JP); Yasutaka MIZOMOTO, Kikuchi-gun, Kumamoto (JP); Hayato TANOUE, Kikuchi-gun, Kumamoto (JP)

(21) Appl. No.: 18/549,610

(22) PCT Filed: Feb. 25, 2022
(86) PCT No.: PCT/JP2022/008066

§ 371 Date: Sep. 8, 2023

(30) Foreign Application Priority Data
Mar. 9, 2021 (JP) 2021-037190

(51) Int. Cl. H01L 21/78; H01L 21/67; H01L 21/683

(52) U.S. Cl. CPC H01L 21/78; H01L 21/67092; H01L 21/6836

(57) ABSTRACT

A semiconductor chip manufacturing method includes (A) to (E) described below. (A) preparing a stacked substrate including a first semiconductor substrate, a device layer, a separation layer, and a third semiconductor substrate in this order. (B) dicing the first semiconductor substrate, the device layer, and the separation layer. (C) attaching the diced stacked substrate to a tape from an opposite side to the third semiconductor substrate, and mounting the diced stacked substrate to a frame with the tape therebetween. (D) radiating, after mounting the stacked substrate to the frame, a laser beam penetrating the third semiconductor substrate to the separation layer to form a modification layer at an interface between the third semiconductor substrate and the separation layer, or at an inside of the separation layer. (E) separating the third semiconductor substrate and the separation layer starting from the modification layer.

### TECHNICAL FIELD

The various aspects and embodiments described herein pertain generally to a semiconductor chip manufacturing method and a substrate processing apparatus.

### BACKGROUND

Patent Documents 1 and 2 describe a method of manufacturing a SOI (Silicon on Insulator) substrate. The manufacturing method disclosed in Patent Document 1 includes the following processes (a) to (f). (a) After forming a buried oxide film layer at a predetermined depth of a first wafer, an oxide film is formed on the first wafer. (b) A hydrogen-buried layer is formed in the first wafer at a depth deeper than that of the buried oxide film layer. (c) A second wafer is bonded on the oxide film. (d) The first wafer under the hydrogen-buried layer is removed so that the first wafer between the buried oxide film layer and the hydrogen-buried layer is exposed. (e) The first wafer exposed in the process (d) and the buried oxide film layer are sequentially removed so that the first wafer between the buried oxide film layer and the oxide film is exposed. (f) A predetermined thickness of the first wafer exposed in the process (e) is removed.

In the manufacturing method described in Patent Document 2, a silicon substrate for forming an active layer made of single crystalline silicon is prepared, and a buried insulating layer is formed on a surface of the silicon substrate. Then, hydrogen ions are implanted through the buried insulating layer to form an ion-implanted layer for separation, and Ar ions or the like are implanted between the ion-implanted layer and the buried insulating layer to form an amorphous layer. Then, the silicon substrate and a support substrate are bonded to each other with the buried insulating layer therebetween. Thereafter, by performing a heating processing, a portion of the silicon substrate where the ion-implanted layer is formed is separated by a smart cut method to thereby form the active layer. Further, by performing a heating processing, the amorphous layer is polycrystalized to thereby form a polycrystalline silicon layer serving as a gettering site.

### PRIOR ART DOCUMENT

Patent Document 1: Japanese Patent Laid-open Publication No. 2006-173568
Patent Document 2: Japanese Patent Laid-open Publication No. 2009-218381

### DISCLOSURE OF THE INVENTION

### Problems to be Solved by the Invention

Exemplary embodiments provide a technique of improving productivity of semiconductor chips.

### Means for Solving the Problems

In an exemplary embodiment, a semiconductor chip manufacturing method includes (A) to (E) described below. (A) preparing a stacked substrate including a first semiconductor substrate, a device layer, a separation layer, and a third semiconductor substrate in this order. (B) dicing the first semiconductor substrate, the device layer, and the separation layer. (C) attaching the diced stacked substrate to a tape from an opposite side to the third semiconductor substrate, and mounting the diced stacked substrate to a frame with the tape therebetween. (D) radiating, after mounting the stacked substrate to the frame, a laser beam penetrating the third semiconductor substrate to the separation layer to form a modification layer at an interface between the third semiconductor substrate and the separation layer, or at an inside of the separation layer. (E) separating the third semiconductor substrate and the separation layer starting from the modification layer formed at the interface between the third semiconductor substrate and the separation layer or at the inside of the separation layer.

### Effect of the Invention

According to the exemplary embodiments, it is possible to improve productivity of semiconductor chips.

### BRIEF DESCRIPTION OF THE DRAWINGS

FIG. 1 is a flowchart illustrating a manufacturing method of a stacked substrate according to an exemplary embodiment.

FIG. 2A is a cross sectional view showing an example of a process S102, FIG. 2B is a cross sectional view showing an example of a process S103, and FIG. 2C is a cross sectional view showing the example of the process S103 subsequent to that of FIG. 2B.

FIG. 3 is a flowchart showing an example of a processing subsequent to that of FIG. 1.

FIG. 4A is a cross sectional view showing an example of a process S201, FIG. 4B is a cross sectional view showing an example of a process S202, FIG. 4C is a cross sectional view showing an example of a process S203, FIG. 4D is a cross sectional view showing the example of the process S203 subsequent to that of FIG. 4C, and FIG. 4E is a cross sectional view showing an example of a process S204.

FIG. 5 is a flowchart showing an example of a processing subsequent to that of FIG. 3.

FIG. 6A is a cross sectional view illustrating an example of a stacked substrate prepared before a process S501, FIG. 6B is a cross sectional view showing an example of the process S501, and FIG. 6C is a cross sectional view showing an example of a process S502.

FIG. 7A is a cross sectional view showing an example of a process S503, FIG. 7B is a cross sectional view showing an example of a process S504, and FIG. 7C is a cross sectional view showing the example of the process S504 subsequent to that of FIG. 7B.

FIG. 8 is a plan view illustrating a substrate processing apparatus according to the exemplary embodiment.

### DETAILED DESCRIPTION

Hereinafter, exemplary embodiments will be described with reference to the accompanying drawings. In the various drawings, same or corresponding parts will be assigned same reference numerals, and redundant description thereof will be omitted. In the present specification, the X-axis direction, the Y-axis direction and the Z-axis direction are orthogonal to each other. Further, the X-axis direction and the Y-axis direction are horizontal directions, whereas the Z-axis direction is a vertical direction.

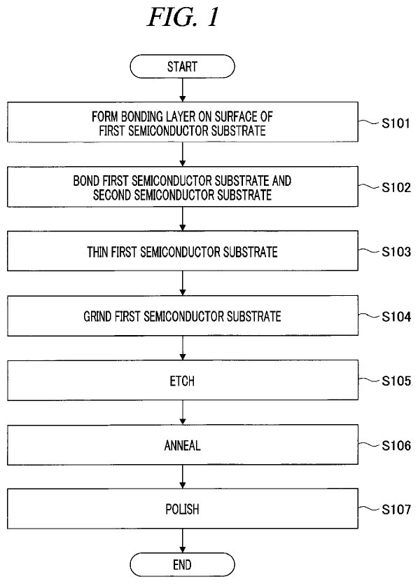

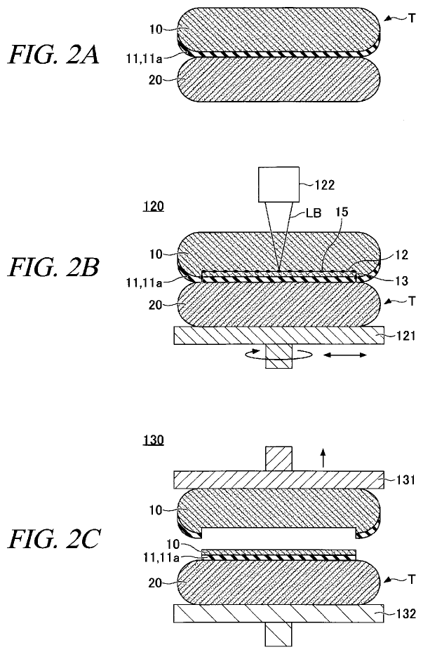

Referring to FIG. 1 and FIG. 2, a manufacturing method of a stacked substrate according to an exemplary embodiment will be described. The manufacturing method of the stacked substrate includes processes S101 to S107, as shown in FIG. 1, for example. Further, the manufacturing method of the stacked substrate may include the processes S101 to S103 at least. It should be noted that the order of the processes S104 to S107 is not limited to that shown in FIG. 1. For example, the process S106 may be performed after the process S107.

The process S101 includes forming a bonding layer 11 on a surface of a first semiconductor substrate 10. The bonding layer 11 includes an oxide layer 11a. The oxide layer 11a is, for example, a thermal oxide layer formed by a thermal oxidation method. In the thermal oxidation method, the heated surface of the first semiconductor substrate 10 is exposed to oxygen or water vapor, so that the oxide layer 11a grows from the surface of the first semiconductor substrate 10 toward the inside thereof. The thermal oxidation method enables formation of the oxide layer 11a having high density, as compared to a chemical vapor deposition (CVD) method or the like to be described later, so that the oxide layer 11a featuring excellent insulating property can be obtained. The thickness of the oxide layer 11a is set such that laser lift-off to be described later can be easily performed.

The first semiconductor substrate 10 is, for example, a silicon wafer, and the oxide layer 11a is, for example, a silicon oxide layer. Further, the first semiconductor substrate 10 is not limited to the silicon wafer, but it may be a compound semiconductor wafer or the like. Further, the oxide layer 11a may be formed by a CVD method or an atomic layer deposition (ALD) method.

The process S102 includes bonding the first semiconductor substrate 10 and a second semiconductor substrate 20 with the bonding layer 11 therebetween, as illustrated in FIG. 2A. No oxide layer or the like is formed on a surface of the second semiconductor substrate 20, and the second semiconductor substrate 20 and the oxide layer 11a of the bonding layer 11 are in direct contact with each other. The second semiconductor substrate 20 is, for example, a silicon wafer. A stacked substrate T including the first semiconductor substrate 10, the bonding layer 11, and the second semiconductor substrate 20 is obtained.

Before bonding the first semiconductor substrate 10 and the second semiconductor substrate 20, the surface of the second semiconductor substrate 20 and a surface of the oxide layer 11a of the bonding layer 11 may be activated by plasma or the like, or may be hydrophilized through the supply of water or water vapor. At the time of the bonding, a hydrogen bond between OH groups may be formed. Further, a covalent bond may also be formed by a dehydration condensation reaction of the hydrogen bond. Since the solids are directly bonded to each other without using a liquid adhesive, position deviation due to deformation of the adhesive or the like can be suppressed. In addition, it is also possible to suppress formation of an inclination due to uneven thickness of the adhesive.

The process S103 includes thinning the first semiconductor substrate 10. First, as shown in FIG. 2B, a modification layer 15 is formed by a laser beam LB on a first division plane 12 along which the first semiconductor substrate 10 is to be divided in a thickness direction. At this time, the modification layer 15 may also be formed by the laser beam LB on a ring-shaped second division plane 13 set as an outer edge of the first division plane 12.

The laser beam LB is radiated to the inside of the first semiconductor substrate 10 from, for example, the surface of the first semiconductor substrate 10 opposite to the second semiconductor substrate 20. The modification layer 15 is formed in a dotted shape, and is formed in plurality on the first division plane 12 and the second division plane 13. The formation position of the modification layer 15 is moved by using a galvano scanner or an XYθ stage. When the modification layers 15 are formed, a crack CR connecting the modification layers 15 are also formed.

Next, as shown in FIG. 2C, by dividing the first semiconductor substrate 10 starting from the modification layer 15 formed on the first division plane 12, the first semiconductor substrate 10 bonded to the second semiconductor substrate 20 with the bonding layer 11 therebetween is thinned. As a result, the stacked substrate T including the thinned first semiconductor substrate 10, the bonding layer 11, and the second semiconductor substrate 20 is obtained. At this time, a bevel of the first semiconductor substrate 10 may be removed by dividing the first semiconductor substrate 10 starting from the modification layer 15 formed on the second division plane 13.

By way of example, an upper chuck 131 holds the first semiconductor substrate 10, and a lower chuck 132 holds the second semiconductor substrate 20. Meanwhile, the vertical arrangement of the first semiconductor substrate 10 and the second semiconductor substrate 20 may be reversed. That is, the upper chuck 131 may hold the second semiconductor substrate 20, and the lower chuck 132 may hold the first semiconductor substrate 10. Then, when the upper chuck 131 is raised with respect to the lower chuck 132, the crack expands in a planar fashion starting from the modification layer 15, so that the first semiconductor substrate 10 is divided along the first division plane 12 and the second division plane 13.

In addition, instead of raising the upper chuck 131 or concurrently with the raising of the upper chuck 131, the lower chuck 132 may be lowered. Further, the lower chuck 132 may be rotated around a vertical axis.

In the processes S104 to S107, a distortion remaining on the thinned first semiconductor substrate 10 is removed to improve the quality of the first semiconductor substrate 10. Thus, as will be described later, a defect of a first device layer formed on the surface of the first semiconductor substrate 10 can be reduced.

In the process 104, the surface of the thinned first semiconductor substrate 10 is ground. In the process S105, the surface of the thinned first semiconductor substrate 10 is etched. In the process S106, the thinned first semiconductor substrate 10 is annealed. In the process S107, the thinned first semiconductor substrate 10 is polished.

When the first semiconductor substrate is thinned by the smart cut method as in the prior art, a large amount of electric power is consumed when the hydrogen ions are implanted into the first semiconductor substrate. Further, the depth at which the hydrogen ions can be implanted into the first semiconductor substrate is about 1 μm at maximum, and the thickness of the thinned first semiconductor substrate is about 1 μm at maximum. Therefore, in order to add a semiconductor layer to the thinned first semiconductor substrate, a processing such as epitaxial growth is required. In addition, since radioactivity is generated when the hydrogen ions are implanted into the first semiconductor substrate, a special chamber for shielding the radioactivity is needed.

According to the present exemplary embodiment, as described above, the modification layer 15 is formed with the laser beam LB, and the first semiconductor substrate 10 is thinned by being separated starting from the modification layer 15. Through the radiation of the laser beam LB, the amount of electric power consumption can be reduced as compared to the case where the implantation of the hydrogen ions is performed. In addition, the depth at which the modification layer 15 is formed can be controlled by adjusting the condensing point of the laser beam LB or the like, so that the thickness of the thinned first semiconductor substrate 10 can be suppressed from becoming too small. Therefore, such a processing as the epitaxial growth may be omitted. Furthermore, since the radiation of the laser beam LB does not involve the generation of radioactivity unlike the implantation of the hydrogen ions, a special chamber for shielding the radioactivity is not required. Therefore, the productivity of the stacked substrate T including the thinned first semiconductor substrate 10, the bonding layer 11, and the second semiconductor substrate 20 can be improved, so that the production cost of the stacked substrate T can be reduced.

As described above, the stacked substrate T including the thinned first semiconductor substrate 10, the bonding layer 11, and the second semiconductor substrate 20 is obtained. The thickness of the thinned first semiconductor substrate 10 is smaller than the thickness of the second semiconductor substrate 20. When each of the first semiconductor substrate 10 and the second semiconductor substrate 20 is the silicon wafer and the oxide layer 11a of the bonding layer 11 is the silicon oxide layer, the stacked substrate T obtained by the manufacturing method shown in FIG. 1 becomes a so-called SOI (Silicon on Insulator) substrate.

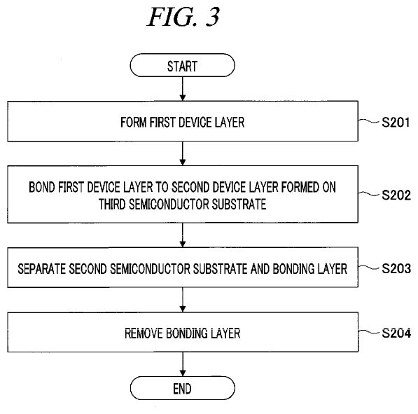

According to the present exemplary embodiment, as shown in FIG. 3, a first device layer 16 is formed on the surface of the thinned first semiconductor substrate 10, as will be elaborated later. The first device layer 16 includes, for example, a semiconductor element. After the first device layer 16 is formed, the modification layer 15 is formed with the laser beam LB that penetrates the second semiconductor substrate 20. The oxide layer 11a of the bonding layer 11 has high absorptance for the laser beam LB, so the modification layer 15 is formed at an interface between the second semiconductor substrate 20 and the bonding layer 11. Further, the modification layer 15 may be formed at an inside of the bonding layer 11. Then, the second semiconductor substrate 20 and the bonding layer 11 are separated starting from the modification layer 15. When the stacked substrate T including the oxide layer 11a is used, the laser lift-off may be performed regardless of the kind of the first device layer 16.

In addition, according to the present exemplary embodiment, the bonding layer 11 is formed on the first semiconductor substrate 10, not on the second semiconductor substrate 20. Therefore, the bonding layer 11 is firmly bonded to the first semiconductor substrate 10. The separation does not occur at an interface between the bonding layer 11 and the first semiconductor substrate 10, but the separation between the bonding layer 11 and the second semiconductor substrate 20 is performed. Thus, the separation strength is low, which eases the separation. The separated second semiconductor substrate 20 is bonded to a new first semiconductor substrate 10 to be reused.

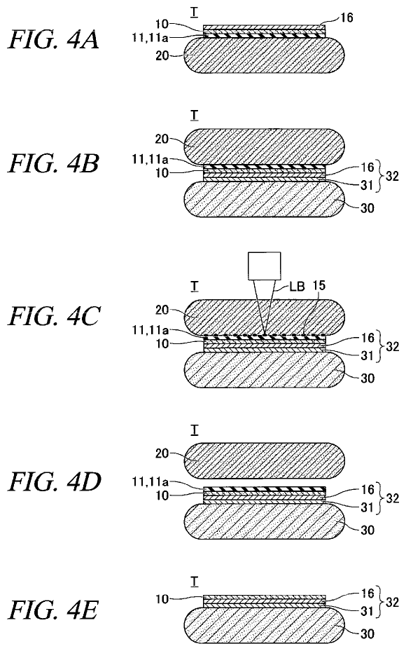

Now, with reference to FIG. 3 to FIG. 4E, an example of a processing subsequent to that of FIG. 1 will be described. The manufacturing method of the stacked substrate includes processes S201 to S204, as shown in FIG. 3, for example. The process S201 includes forming the first device layer 16 on the surface of the thinned first semiconductor substrate 10, as shown in FIG. 4A. The first device layer 16 includes, by way of example, an image sensor. The image sensor is of, for example, a BSI (Back Side Illumination) type.

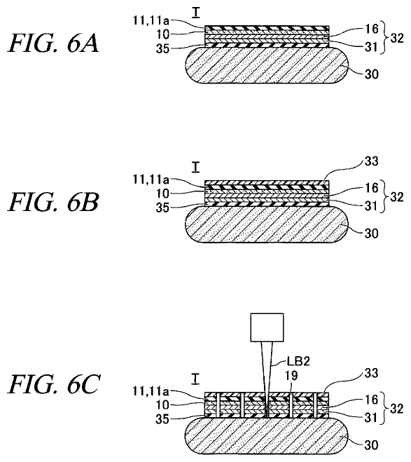

The process S202 includes bonding the first device layer 16 and a second device layer 31 formed on a third semiconductor substrate 30 to face each other, as shown in FIG. 4B. The second device layer 31 is formed on the third semiconductor substrate 30 before being bonded to the first device layer 16. A separation layer 35 may be exist between the third semiconductor substrate 30 and the second device layer 31, as shown in FIG. 6A. The third semiconductor substrate 30 is, for example, a silicon wafer, and the second device layer 31 includes, for example, a logic circuit of the image sensor. The first device layer 16 and the second device layer 31 constitute a device layer 32 together.

Before the first device layer 16 and the second device layer 31 are bonded, a surface of the first device layer 16 and a surface of the second device layer 31 may be activated by plasma or the like, or may be hydrophilized through the supply of water or water vapor. At the time of the bonding, a hydrogen bond between OH groups is formed. In addition, a covalent bond may also be formed by a dehydration condensation reaction of the hydrogen bond.

In the process S203, the second semiconductor substrate 20 and the bonding layer 11 are separated. First, as shown in FIG. 4C, the modification layer 15 is formed at the interface between the second semiconductor substrate 20 and the bonding layer 11 by using the laser beam LB penetrating the second semiconductor substrate 20. The oxide layer 11a of the bonding layer 11 has high absorptance for the laser beam LB, so the modification layer 15 is formed at the interface between the second semiconductor substrate 20 and the oxide layer 11a. Further, the modification layer 15 may be formed inside the bonding layer 11.

Next, as shown in FIG. 4D, starting from the modification layer 15 formed at the interface between the second semiconductor substrate 20 and the bonding layer 11 (or formed inside the bonding layer 11), the second semiconductor substrate 20 and the bonding layer 11 are separated. For example, a non-illustrated upper chuck holds the second semiconductor substrate 20, and a non-illustrated lower chuck holds the third semiconductor substrate 30. Meanwhile, the vertical arrangement of the second semiconductor substrate 20 and the third semiconductor substrate 30 may be reversed. Then, when the upper chuck is raised with respect to the lower chuck, a crack expands planarly starting from the modification layer 15, so that the second semiconductor substrate 20 and the bonding layer 11 are separated.

Further, instead of raising the upper chuck or concurrently with the raising of the upper chuck, the lower chuck may be lowered. Further, the lower chuck may be rotated around a vertical axis.

The process S204 includes removing the bonding layer 11 after separating the second semiconductor substrate 20 and the bonding layer 11, as shown in FIG. 4E. The bonding layer 11 is removed by chemical mechanical polishing (CMP) or the like. As a result, the thinned first semiconductor substrate 10 is exposed on a surface of the stacked substrate T.

Here, the bonding layer 11 does not need to be removed if it does not affect a subsequent process. In addition, in case of using the bonding layer 11 as a gettering layer to be described later, the bonding layer 11 is not removed. The gettering layer is a layer that captures impurities such as heavy metals.

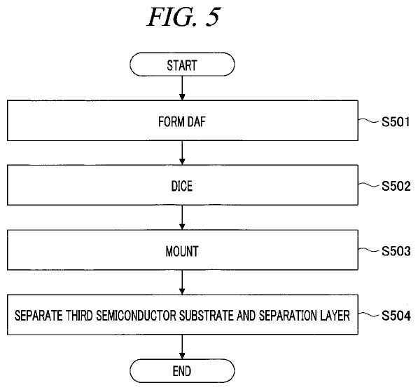

Now, with reference to FIG. 5 to FIG. 7C, an example of a processing subsequent to that of FIG. 3 will be described. The manufacturing method of the stacked substrate includes processes S501 to S504, as shown in FIG. 5, for example. By the processing shown in FIG. 3, the stacked substrate T shown in FIG. 6A is obtained. The stacked substrate T has the first semiconductor substrate 10, the device layer 32, the separation layer 35, and the third semiconductor substrate 30 arranged in this order. Like the bonding layer 11, the separation layer 35 may contain an oxide layer. Further, the separation layer 35 may also contain a nitride layer. It is also possible to form the modification layer 15 in the nitride layer. In addition, the separation layer 35 may have a multilayer structure. Also, the stacked substrate T may further have the bonding layer 11 functioning as a gettering layer on a surface of the first semiconductor substrate 10 opposite to the device layer 32.

As described above, the device layer 32 may include the first device layer 16 and the second device layer 31. The first device layer 16 includes, for example, a semiconductor memory. The second device layer 31 includes, for example, a peripheral circuit (also referred to as “peripheral”) of the semiconductor memory, an input/output circuit (also referred to as “IO”) of the semiconductor memory, and the like.

The process S501 includes, as shown in FIG. 6B, forming a die attach film (DAF) 33 on the surface of the bonding layer 11 (or the first semiconductor substrate 10 when there is no bonding layer 11). The die attach film 33 is an adhesive sheet for die bonding. The die attach film 33 is used for the stacking of semiconductor chips and the like. The die attach film 33 may be either conductive or insulating. The die attach film 33 is obtained by coating a liquid material and drying it.

The process S502 includes dicing the bonding layer 11, the first semiconductor substrate 10, the device layer 32, and the separation layer 35, as shown in FIG. 6C. A groove 19 is formed through the bonding layer 11, the first semiconductor substrate 10, the device layer 32, and the separation layer 35. When the die attach film 33 is previously formed on the bonding layer 11, the die attach film 33 is also diced, and the groove 19 is formed through the die attach film 33 as well. The dicing may be carried out by, for example, a laser dicing method or a blade dicing method.

The laser dicing includes an ablation processing with a laser beam LB2. The die attach film 33, the bonding layer 11, the first semiconductor substrate 10, the device layer 32, and the separation layer 35 absorb the laser beam LB2 and generate heat to be sublimated or evaporated. As a result, the groove 19 is formed.

A controller may change the energy of the laser beam LB2 when dicing the first semiconductor substrate 10 and when dicing the device layer 32 and the separation layer 35. For example, when processing the first semiconductor substrate 10, the energy is set such that silicon can be processed. Meanwhile, when processing the device layer 32 and the separation layer 35, the energy is set such that a conductive film and an oxide film can be processed while silicon cannot be processed. Thus, when the device layer 32 and the separation layer 35 are processed, a damage to the third semiconductor substrate 30 can be suppressed.

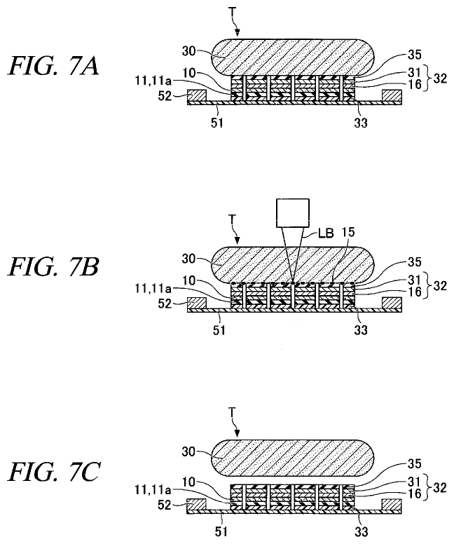

The process S503 includes, as shown in FIG. 7A, attaching the stacked substrate T to a tape 51 disposed on the opposite side to the third semiconductor substrate 30 and mounting the stacked substrate T to a frame 52 with the tape 51 therebetween. The frame 52 is formed in an annular shape, and the tape 51 is attached to the frame 52 so as to cover an opening of the frame 52.

The die attach film 33 is disposed between the bonding layer 11 (the first semiconductor substrate 10 when there is no bonding layer 11) and the tape 51. The die attach film 33 is formed in advance on the bonding layer 11 or the like in the present exemplary embodiment, but it may be previously attached to a surface of the tape 51. In the latter case, the process S503 and the process S501 are performed at the same time. In this case, the dicing of the die attach film 33 may be performed after the process S504 to be described below.

In the process S504, the third semiconductor substrate 30 and the separation layer 35 are separated in the same way as in the process S203 of FIG. 3. First, as illustrated in FIG. 7B, the modification layer 15 is formed at an interface between the third semiconductor substrate 30 and the separation layer 35 by using the laser beam LB penetrating the third semiconductor substrate 30. Further, the modification layer 15 may be formed at an inside of the separation layer 35. Thereafter, as shown in FIG. 7C, the third semiconductor substrate 30 and the separation layer 35 are separated starting from the modification layer 15 formed at the interface between the third semiconductor substrate 30 and the separation layer 35. Scattering of semiconductor chips can be suppressed by the tape 51 even after the separation. The semiconductor chips are picked up one by one.

After the third semiconductor substrate 30 and the separation layer 35 are separated, the bonding layer 11 remains on the surface of the first semiconductor substrate 10. The remaining bonding layer 11 is used as the gettering layer for trapping impurities such as heavy metals. Therefore, an additional process of forming the gettering layer is not necessary.

Conventionally, the device layer 32 is formed on the surface of the first semiconductor substrate 10 having a large thickness and is diced with a blade. Subsequently, a protective tape is attached to the device layer 32, and the first semiconductor substrate 10 is then ground to be thinned. The blade fully cuts the device layer 32 and also half-cuts the first semiconductor substrate 10. Then, by grinding the first semiconductor substrate 10 from the side opposite to the device layer 32, the first semiconductor substrate 10 is divided, so that a plurality of semiconductor chips are obtained. Afterwards, a process of forming a gettering layer on the ground surface of the first semiconductor substrate 10, a process of disposing the tape 51 on the opposite side to the protective tape with the first semiconductor substrate 10 therebetween and mounting the first semiconductor substrate 10 to the frame 52 with the tap 51 therebetween, a process of removing the protective tape, and the like are performed.

According to the present exemplary embodiment, before the device layer 32 is formed, the first semiconductor substrate 10 is already thinned (see FIGS. 4A to 4E). (1) Since the first semiconductor substrate 10 is not ground after the device layer 32 is formed, unlike in the prior art, the damage to the device layer 32 and the first semiconductor substrate 10 can be suppressed. Further, according to the present exemplary embodiment, the device layer 32 and the first semiconductor substrate 10 are diced to obtain the plurality of semiconductor chips. Then, the first semiconductor substrate 10 is mounted to the frame 52 with the tape 51, which is disposed on the opposite side to the third semiconductor substrate 30, therebetween. Thereafter, the third semiconductor substrate 30 is removed by the laser lift-off. The third semiconductor substrate 30 is harder than the conventional protective tape. (2) Since the semiconductor chips can be reinforced with the third semiconductor substrate 30 until the third semiconductor substrate 30 is removed, the damage to the semiconductor chips can be suppressed. (3) Unlike in the prior art, it is unnecessary to attach and remove the protective tape. (4) Since the bonding layer 11 left after the third semiconductor substrate 30 is removed can be used as the gettering layer, the process of forming the gettering layer is not required. As stated above, according to the present exemplary embodiment, productivity of the semiconductor chips can be improved.

Further, in the present exemplary embodiment, although the stacked substrate T having the bonding layer 11 formed on the first semiconductor substrate 10 is prepared, as shown in FIG. 6A, the bonding layer 11 may be formed on the second semiconductor substrate 20. Even in this case, the above-stated effects (1) to (4) can still be achieved, and the productivity of the semiconductor chips can be improved. Further, in the case of preparing the stacked substrate T in which the bonding layer 11 is formed on the first semiconductor substrate 10 as illustrated in FIG. 6A, (5) the separation of the second semiconductor substrate 20 and the bonding layer 11 can be easily carried out.

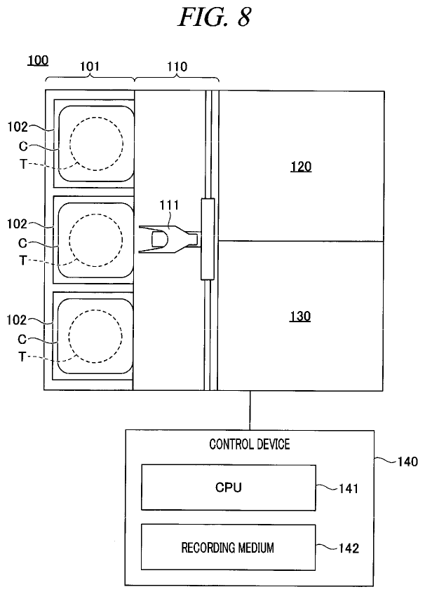

Now, with reference to FIG. 8, etc., a substrate processing apparatus 100 configured to perform the process S103 of FIG. 1 will be described. The substrate processing apparatus 100 includes a carry-in/out unit 101, a transfer unit 110, a laser processing unit 120, a dividing unit 130, and a controller 140.

The carry-in/out unit 101 has placement units 102 in each of which a cassette C is placed. The cassette C accommodates a plurality of stacked substrates T shown in FIG. 2A, for example. The stacked substrate T includes the first semiconductor substrate 10, the second semiconductor substrate 20, and the bonding layer 11 that bonds the first semiconductor substrate 10 and the second semiconductor substrate 20. The number of the placement units 102 and the number of the cassettes C are not limited to those shown in FIG. 8.

The transfer unit 110 is disposed next to the carry-in/out unit 101, the laser processing unit 120, and the dividing unit 130 to transfer the stacked substrate T to these units. The transfer unit 110 has a transfer arm 111 configured to hold the stacked substrate T. The transfer arm 111 is configured to be movable in horizontal directions (both in the X-axis direction and the Y-axis direction) and a vertical direction, and pivotable around a vertical axis.

As shown in FIG. 2B, the laser processing unit 120 is configured to form the modification layer 15 with the laser beam LB on the division plane along which the stacked substrate T is to be divided in the thickness direction thereof. The laser processing unit 120 includes, by way of example, a stage 121 configured to hold the stacked substrate T, and an optical system 122 configured to radiate the laser beam LB to the stacked substrate T held by the stage 121. The stage 121 is, for example, an XYθ stage or an XYZθ stage. The optical system 122 includes, for example, a condensing lens. The condensing lens condenses the laser beam LB toward the stacked substrate T. The optical system 122 may further include a galvano scanner.

As shown in FIG. 2C, the dividing unit 130 is configured to divide the stacked substrate T starting from the modification layer 15 formed on the division plane. The dividing unit 130 includes, for example, the upper chuck 131 and the lower chuck 132. The upper chuck 131 is configured to hold the first semiconductor substrate 10, and the lower chuck 132 is configured to hold the second semiconductor substrate 20. However, the vertical arrangement of the first semiconductor substrate 10 and the second semiconductor substrate 20 may be reversed. Then, when the upper chuck 131 is raised with respect to the lower chuck 132, the crack spreads in the planar shape starting from the modification layer 15, so that the stacked substrate T is divided along the first division plane 12, etc. Here, instead of raising the upper chuck 131 or concurrently with the raising of the upper chuck 131, the lower chuck 132 may be lowered. Further, the lower chuck 132 may be rotated around a vertical axis.

The controller 140 is, for example, a computer, and includes a CPU (Central Processing Unit) 141 and a recording medium 142 such as a memory, as shown in FIG. 8. The recording medium 142 stores therein a program for controlling various processings performed in the substrate processing apparatus 100. The controller 140 controls the operation of the substrate processing apparatus 100 by causing the CPU 141 to execute the program stored in the recording medium 142.

The controller 140 sets the division plane to be located inside the first semiconductor substrate 10. The controller 140 forms the modification layer 15 on the first division plane 12, and divides the first semiconductor substrate 10 starting from the formed modification layer 15, thus allowing the first semiconductor substrate 10 bonded to the second semiconductor substrate 20 with the bonding layer 11 therebetween to be thinned.

In addition, the substrate processing apparatus 100 shown in FIG. 8 may also be used in processes other than the process S103 of FIG. 1. For example, the substrate processing apparatus 100 may also be used in the process S203 of FIG. 3 and the process S504 of FIG. 5.

When performing the process S203 of FIG. 3, the controller 140 sets the interface between the second semiconductor substrate 20 and the bonding layer 11 as the division plane, and separates the second semiconductor substrate 20 and the bonding layer 11 starting from the modification layer 15 formed at the interface therebetween. In this case, in the dividing unit 130, the upper chuck 131 holds the second semiconductor substrate 20, and the lower chuck 132 holds the third semiconductor substrate 30. Here, the modification layer 15 may be formed inside the bonding layer 11.

When performing the process S504 of FIG. 5, the controller 140 sets the interface between the third semiconductor substrate 30 and the separation layer 35 as the division plane, and separates the third semiconductor substrate 30 and the separation layer 35 starting from the modification layer 15 formed at the interface therebetween. In this case, in the dividing unit 130, the upper chuck 131 holds the third semiconductor substrate 30 and the lower chuck 132 holds the tape 51. Here, the modification layer 15 may be formed inside the separation layer 35. Further, the transfer arm 111 of the transfer unit 110 holds the stacked substrate T by holding the frame 52 shown in FIG. 7A to FIG. 7C.

So far, the exemplary embodiment of the semiconductor chip manufacturing method and the substrate processing apparatus according to the present disclosure have been described. However, the present disclosure is not limited to the above-described exemplary embodiment and the like. Various changes, modifications, substitutions, additions, deletions and combinations may be made within the scope of the claims, which are all incorporated within a technical scope of the present disclosure.

The present application claims priority to Japanese Patent Application No. 2021-037190, filed on Mar. 9, 2021, which application is hereby incorporated by reference in their entirety.

### EXPLANATION OF CODES

10: First semiconductor substrate
32: Device layer
35: Separation layer
30: Third semiconductor substrate
51: Tape
52: Frame
T: Stacked substrate

1. A semiconductor chip manufacturing method, comprising:
preparing a stacked substrate including a first semiconductor substrate, a device layer, a separation layer, and a third semiconductor substrate in this order;
dicing the first semiconductor substrate, the device layer, and the separation layer;
attaching the diced stacked substrate to a tape from an opposite side to the third semiconductor substrate, and mounting the diced stacked substrate to a frame with the tape therebetween;
radiating, after mounting the stacked substrate to the frame, a laser beam penetrating the third semiconductor substrate to the separation layer to form a modification layer at an interface between the third semiconductor substrate and the separation layer, or at an inside of the separation layer; and
separating the third semiconductor substrate and the separation layer starting from the modification layer formed at the interface between the third semiconductor substrate and the separation layer or at the inside of the separation layer.

2. The semiconductor chip manufacturing method of claim 1,
wherein the stacked substrate includes a gettering layer formed on a surface of the first semiconductor substrate opposite to the device layer before the dicing, and
the dicing includes dicing the gettering layer.

3. The semiconductor chip manufacturing method of claim 2,
wherein the gettering layer is a thermal oxide layer formed by thermally oxidizing the surface of the first semiconductor substrate.

4. The semiconductor chip manufacturing method of claim 2,
wherein the stacked substrate includes a die attach film formed on a surface of the gettering layer opposite to the first semiconductor substrate before the dicing, and
the dicing includes dicing the die attach film.

5. The semiconductor chip manufacturing method of claim 1,
wherein the stacked substrate includes a die attach film formed on a surface of the first semiconductor substrate opposite to the device layer before the dicing, and
the dicing includes dicing the die attach film.

6. The semiconductor chip manufacturing method of claim 1,
wherein the mounting of the stacked substrate to the frame includes attaching a die attach film formed on a surface of the tape and the first semiconductor substrate to face each other.

7. The semiconductor chip manufacturing method of claim 1,
wherein the device layer includes a first device layer formed on a surface of the first semiconductor substrate, and a second device layer bonded to the first device layer.

8. A substrate processing apparatus, comprising:
a transfer unit configured to transfer a stacked substrate, which includes a first semiconductor substrate, a device layer, a separation layer, and a third semiconductor substrate in this order and in which the first semiconductor substrate, the device layer and the separation layer are diced, while being attached to a tape from an opposite side to the third semiconductor substrate and being mounted to a frame with the tape therebetween;
a laser processing unit configured to form a modification layer with a laser beam on a division plane along which the stacked substrate is to be divided in a thickness direction thereof;
a dividing unit configured to divide the stacked substrate starting from the modification layer formed on the division plane; and
a controller configured to control the transfer unit, the laser processing unit, and the dividing unit,
wherein the controller radiates the laser beam penetrating the third semiconductor substrate to the separation layer to form the modification layer at an interface between the third semiconductor substrate and the separation layer or at an inside of the separation layer, and separates the third semiconductor substrate and the separation layer starting from the modification layer formed at the interface between the third semiconductor substrate and the separation layer or at the inside of the separation layer.

9. The substrate processing apparatus of claim 8,
wherein the stacked substrate includes a gettering layer diced in advance on a surface of the first semiconductor substrate opposite to the device layer.

10. The substrate processing apparatus of claim 9,
wherein the gettering layer is a thermal oxide layer formed by thermally oxidizing the surface of the first semiconductor substrate.
